(19) United States
(12) Patent Application Publication
(10) Pub. No.: US 2005/0274601 A1
(43) Pub. Date: Dec. 15, 2005

(54) Method for manufacturing magnetic recording medium

(75) Inventors: Kenichi Moriwaki, Kanagawa (JP); Kazuyuki Usuki, Kanagawa (JP); Junji Nakada, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/141,046

(22) Filed: Jun. 1, 2005

(30) Foreign Application Priority Data
Jun. 11, 2004 (JP) P.2004-173765

(51) Int. Cl. C23C 14/32

(52) U.S. Cl. 204/192.2; 204/192.14

(57) ABSTRACT

A method for manufacturing a magnetic recording medium, the method comprising forming a magnetic layer on at least one side of a flexible polymer support by a sputtering method, wherein the flexible polymer support contains at least one of polyethylene terephthalate, polyethylene naphthalate, polyamide and polyimide, the forming of a magnetic layer is carried out while carrying the flexible polymer support along a roll having a maximum surface roughness of from 0.01 to 0.4 μm, and a deposition rate in the sputtering method for forming of a magnetic layer is from 0.5 to 17 nm/sec.

### FIELD OF THE INVENTION

The present invention relates to a manufacturing method of a magnetic recording medium.

### BACKGROUND OF THE INVENTION

With the spread of the Internet in recent years, the use form of the computer has been changed, e.g., to the form of processing a great volume of motion picture data and sound data with a personal computer. Along with such a trend, the storage capacity required of the magnetic recording media, such as hard disks, has increased.

In a hard disk apparatus, a magnetic head slightly floats from the surface of a magnetic disk with the rotation of the magnetic disk, and magnetic recording is done by non-contact recording system. This mechanism prevents the magnetic disk from breaking by the touch of the magnetic head and the magnetic disk. With the increase of density of magnetic recording, the flying height of a magnetic head is gradually decreased, and now the flying height of from 10 to 20 nm has been realized by the use of a magnetic disk comprising a specularly polished hyper-smooth glass substrate having provided thereon a magnetic recording layer. Areal recording density and recording capacity of hard disk drive have markedly increased during the past few years by technological innovation, e.g., the improvement of the structure of a head and the improvement of the recording film of a disk, in addition to the flying height reduction of a head.

With the increase of throughput of digital data, there arises a need of moving a high capacity data, such as moving data, by recording on a removable medium. However, since the substrate of a hard disk is made of a hard material and the distance between a head and a disk is extremely narrow as described above, there is the fear of happening of accident by the impact during operation and entraining dusts when a hard disk is tried to be used as a removable medium such as a flexible disk and a rewritable optical disk, and so a hard disk cannot be used.

On the other hand, the supports of flexible disks and magnetic tapes are flexible polymer film supports and they are media capable of contact recording, so that they are excellent in removability and can be manufactured inexpensively. However, now commercially available flexible disks and magnetic tapes are coating type magnetic recording media manufactured by coating magnetic powder with a polymer binder and an abrasive on a polymer film, and deposition type magnetic recording media having a recording layer manufactured by vacuum evaporating a cobalt alloy on a polymer film. Therefore, the high density recording characteristics of the magnetic layers are inferior to those of hard disks having a magnetic layer formed by sputtering, and the achieved recording density of the flexible disks and magnetic tapes is only 1/10 or less of that of hard disks.

Therefore, a ferromagnetic metal thin film type flexible disk having a recording film formed by sputtering similarly to hard disks is proposed. Since the support of the flexible disk is a flexible polymer film, it becomes possible to form the recording film by sputtering while carrying the support in a roll. That is, a long size sample can be manufactured inexpensively. The manufacturing methods and manufacturing apparatus of this type of flexible disks are disclosed in JP-A-10-3663 (The term “JP-A” as used herein refers to an “unexamined published Japanese patent application”.), JP-A-10-11734 and JP-A-2003-99918. However, when it is tried to increase the carrying rate of a support for the purpose of raising productivity, the deposition rate (film-forming rate) has to be increased by using high input of electric power. In the case of hard disks, since glass or aluminum is used as a substrate, a deposition rate can be increased with the use of relatively high electric power input as disclosed in JP-A-11-203653 and JP-A-2002-25044. However, when high input of electric power is used for a flexible polymer film support, heat is applied to the polymer film and at the same time the stress of the formed film is great, so that the flexible polymer film is deformed due to heat. It is possible to suppress the deformation of a support by heat by lowering the deposition rate as disclosed in JP-A-2001-84585. However, the lowering of deposition rate is as a matter of course accompanied by the reduction of productivity, so that the realization is difficult.

In direct read after write and rewritable type optical disks typified by DVD-R and DVD-RW, the head and the disk are not close to each other as in a magnetic disk, therefore they are excellent in removability and widespread. However, from the thickness of light pickup and economical viewpoints, it is difficult for optical disks to take such a disk structure that both surfaces can be used as recording surfaces as in a magnetic disk, which is advantageous for increasing capacity. Further, optical disks are low in areal recording density and also in data transfer rate as compared with magnetic disks, and so their performance is not sufficient yet as rewritable high capacity recording media.

### SUMMARY OF THE INVENTION

As described above, although the requirement for high capacity rewritable and removable recording media is high, those that satisfy performances, reliability and costs are not realized yet.

The present invention has been done in the light of the prior art problems and an object of the invention is to provide a manufacturing method of a magnetic recording medium capable of forming a magnetic layer on at least one side of a flexible polymer support by a sputtering method while maintaining low costs, suppressing the deformation of the flexible polymer support by heat, and maintaining surface smoothness.

The means for solving the above problems are as follows.

(1) A manufacturing method of a magnetic recording medium comprising a process of forming a magnetic layer on at least one side of a flexible polymer support by a sputtering method, wherein the flexible polymer support is a support selected from polyethylene terephthalate (PET), polyethylene naphthalate (PEN), polyamide (PA) and polyimide (PI), the process of forming a magnetic layer is carried out while carrying the flexible polymer support along a roll having a maximum surface roughness (Rz) of from 0.01 to 0.4 μm, and the deposition rate in forming of the magnetic layer is from 0.5 to 17 nm/sec.

(2) The manufacturing method of a magnetic recording medium as described in the above item (1), wherein the carrying rate of the flexible polymer support is 0.1 to 10 m/minute.

According to the invention, a magnetic layer can be formed on at least one side of a flexible polymer support by a sputtering method while maintaining low costs, suppressing the deformation of the flexible polymer support by heat, and maintaining surface smoothness. Accordingly, a magnetic recording medium obtained by the manufacturing method of the invention is capable of high density magnetic recording and has high performances and high reliability.

### BRIEF DESCRIPTION OF THE DRAWINGS

FIG. 1 is a drawing showing a web-carrying sputtering apparatus usable in the manufacturing method of the invention.

### DESCRIPTION OF REFERENCE NUMERALS AND SIGNS

1: Web-carrying sputtering apparatus
W: Continuous web comprising a flexible polymer support
2: Unwinding roller
13: Film-forming chamber
5A: First film-forming roll
5B: Second film-forming roll
8: Winding roll
9A, 9B: First sputtering target
11A, 11B: Second sputtering target
13A, 13B: Third sputtering target

### DETAILED DESCRIPTION OF THE INVENTION

Since a magnetic recording medium manufactured by the manufacturing method of the invention has a magnetic layer comprising a ferromagnetic metal thin film formed by a sputtering method, high density magnetic recording like that by a hard disk and the increase of capacity are possible.

Further, in forming a magnetic layer by a sputtering method in the invention, the surface property of a film (layer)-forming roll, the material of a support and a deposition rate in the sputtering method are properly specified, so that a support is not deformed by heat, surface smoothness can be maintained, and a highly reliable magnetic recording medium can be manufactured inexpensively.

By adopting the manufacturing method of the invention, it becomes possible to obtain a magnetic recording medium capable of high density recording having at least a magnetic layer formed on a long size and rolled flexible polymer support by a sputtering method. Accordingly, even a flat magnetic tape and a flexible disk resisting against contact recording can be obtained according to the manufacturing method of the invention.

According to the manufacturing method in the invention, both magnetic recording media in the form of tape and magnetic recording media in the form of flexible disk can be manufactured with a flexible polymer support.

A flexible disk using a flexible polymer film as a support has a structure having a center hole formed at the central part and is encased in a cartridge formed of plastics, etc. The cartridge is generally provided with an access window covered with a metal shutter, and a magnetic head is introduced to a flexible disk through the access window, whereby recording of signals on the flexible disk and reproduction are performed.

A magnetic tape using a flexible polymer film as a support is cut in a long size, built-in an open reel or a reel cartridge and encased in a cartridge formed of plastics, etc. Signal recording and reproduction are carried out when the magnetic tape unwound from the reel cartridge passes a magnetic head.

A flexible disk comprises a support in the form of a disk comprising a flexible polymer film having on each of both surfaces of the support at least a magnetic layer. It is further preferred that a flexible disk is composed of an undercoat layer for improving a surface property and a gas barrier property, a gas barrier layer having functions of adhesion and a gas barrier property, an under layer for controlling the crystal orientation of a magnetic layer, a magnetic layer, a protective layer for protecting the magnetic layer from corrosion and abrasion, and a lubricating layer for improving running durability and anticorrosion in this order by lamination. Further, when a flexible disk is used as a perpendicular medium, it is preferred that a soft magnetic layer is provided between the support and the magnetic layer. A magnetic tape comprises a support in the form of a tape (tape-like support) comprising a flexible polymer film having on one side of the support at least a magnetic layer, and it is further preferred that a magnetic tape is composed of an undercoat layer, a gas barrier layer, an under layer, a magnetic layer, a protective layer, and a lubricating layer in this order by lamination. The other side of a magnetic tape is a side in contact with a guide roll that the magnetic tape passes by when unwound from the reel cartridge and carried, and it is preferred that a back coat layer of carbon and the like is provided for the purpose of the magnetic tape smoothly passing the guide roll.

A magnetic layer may be an in-plane magnetic recording film having the axis of easy magnetization oriented in the horizontal direction to the substrate or may be a perpendicular magnetic recording film oriented in the perpendicular direction to the substrate. The direction of the axis of easy magnetization can be controlled by the material and crystal structure of an under layer and the composition and film forming condition of a magnetic film.

As the magnetic layer in the invention, CoPtCr magnetic layers generally used in hard disks, magnetic layers having a granular structure capable of film-forming at room temperature, and artificial lattice type laminated magnetic layers can be used. Magnetic recording media having high retentive force and low noise can be achieved by using these metal thin film type magnetic layers.

As the specific examples of the magnetic layers, CoPtCr, CoPtCrB, CoCr, CoPtCrTa, CoPt, CoPtCr—SiO₂, CoPtCr—TiO₂, CoPtCr—Cr₂O₃, CoPtCrB—SiO₂, CoRuCr, CoRuCr—SiO₂, Co/Pt multilayer film, Co/Pd multilayer film, etc., are exemplified, but other magnetic layers can also be used.

The preferred magnetic layers for use in the invention are magnetic layers having a granular structure, and granular magnetic layers comprise a ferromagnetic metal alloy and a nonmagnetic oxide. In a granular structure, a ferromagnetic metal alloy and a nonmagnetic oxide are mixed macroscopically, but they take the structure that a nonmagnetic oxide covers ferromagnetic metal alloy fine particles microscopically. As the nonmagnetic oxides, Si, Zr, Ta, B, Ti, Al, Cr, Ba, Zn, Na, La, In and Pb can be used, but SiOₓ is most preferred taking recording characteristics into consideration. The mixing ratio (molar ratio) of a ferromagnetic metal alloy to a nonmagnetic oxide is preferably in the range of ferromagnetic metal alloy/nonmagnetic oxide of from 95/5 to 80/20, and particularly preferably from 90/10 to 85/15. By adjusting the mixing ratio in the above range, separation among magnetic particles becomes sufficient, coercive force can be ensured, and the quantity of magnetization can be secured, so that signal output can be assured.

The thickness of a magnetic layer is preferably from 5 to 60 nm, more preferably from 5 to 30 nm. When the thickness is in this range, output can be secured by the reduction of noise and the restraint of the influence of thermal fluctuation, the resistance to the stress applied at the time of head-medium contact can be ensured, and running durability can be assured.

Sputtering methods capable of forming a high quality and hyper thin film with ease are adopted in the invention as methods for forming a magnetic layer. As sputtering methods, any of well-known DC sputtering methods, RF sputtering methods and DC pulse sputtering methods can be used in the invention. For obtaining a magnetic recording medium free from deformation of substrate by the influence of deposition rate and heat, it is more preferred to use DC sputtering methods and DC pulse sputtering methods.

When a magnetic layer is formed, the temperature of a support can be freely controlled in the range of from 0 to 200° C. In heating, heating of a support can be controlled by heating with a heater or by heating a film-forming roll. It is preferred to form a magnetic layer in the state of bringing a support into contact with a film-forming roll for avoiding the deformation of the support by heat. When a magnetic layer is formed at room temperature or a low temperature condition, the temperature of a support can be controlled by means of, e.g., cooling a film-forming roll.

General argon gases can be used as the gas in sputtering but other rare gases can also be used. A trace amount of oxygen gas may be introduced for adjusting the oxygen content in a magnetic layer or for the purpose of surface oxidation.

In manufacturing a magnetic layer by a sputtering method, the pressure of Ar is preferably from 0.1 Pa to 10 Pa, and particularly preferably from 0.4 to 7 Pa. When the Ar pressure in film-forming time is 0.1 Pa or more, the separation among magnetic particles can be ensured, and the stress of the magnetic layer is relaxed, so that the deformation of the support and cracking of the film are difficult to occur. By making the Ar pressure in film-forming time 10 Pa or less, crystallizability and film strength can be assured.

In manufacturing a magnetic layer by a sputtering method, the deposition rate is from 0.5 to 17 nm/sec, particularly preferably from 0.5 to 10 nm/sec. When the deposition rate is in this range, not only the support deformation due to heat applied in film-forming time can be inhibited but also the occurrence of cracks on the sputtered film can be prevented. Further, crystallizability and film adhesion can be ensured, as well as productivity can be achieved. It is possible to adjust a deposition rate by optionally determining the kind of a sputtering target, the input of electric power, the pressure in a film-forming chamber, the distance between a sputtering target and a support, and the carrying rate of a support.

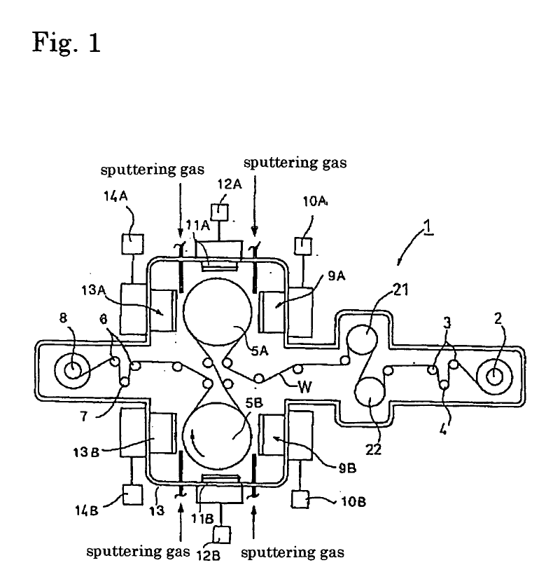

FIG. 1 is a drawing showing a web-carrying sputtering apparatus usable in the manufacturing method of the invention. In FIG. 1, web-carrying sputtering apparatus 1 is an apparatus for forming an under layer and a magnetic layer in this order on both sides of continuous web W comprising a flexible polymer support. Web-carrying sputtering apparatus 1 is equipped with an unwinding shaft, a winding shaft, a plurality of pass rollers for supporting and carrying a continuous web, and a film forming roll, wherein vacuum exhaust can be done by a vacuum exhaust pump not shown in the FIGURE, and sputtering gas is introduced into the apparatus through a mass flow controller not shown in the FIGURE, and web-carrying sputtering apparatus 1 has a plurality of film-forming chambers 13 capable of being set at optional sputtering pressure. In film-forming chambers 13, a cathode is arranged at the counter position to the film forming roll, and the sputtering target for use in film-forming is arranged on the cathode. In web-carrying sputtering apparatus 1, continuous web W comprising a flexible polymer support is delivered from unwinding roller 2 and carried through a pair of heating drums 21 and 22 to first film-forming roll 5A (for obverse film-forming) and second film-forming roll 5B (for reverse film-forming) via a plurality of pass rollers 3 on the delivery side and dancer roller 4 on the delivery side. Further, continuous web W is carried along first film-forming roll 5A and second film-forming roll 5B, and wound on winding roller 8 via a plurality of pass rollers 6 on the winding side and dancer roller 7 on the winding side. The tensile force of continuous web W in carrying is maintained constant by dancer roller 4 on the delivery side and dancer roller 7 on the winding side. Unwinding roller 2, first film-forming roll 5A, second film-forming roll 5B, and winding roller 8 are respectively rotationally driven by a driving unit not shown in the FIGURE. As heating drums 21 and 22, first film-forming roll 5A and second film-forming roll 5B, jacket rolls using steam or induction heating rolls are optionally selected, and the surface temperature of rolls can be controlled. At the facing position to first film-forming roll 5A on the delivery side (the right side of the upper portion in the FIGURE) is arranged first sputtering target 9A for forming a gas barrier layer (described later) by sputtering on the obverse of continuous web W going along first film-forming roll 5A. Direct current sputtering electric source 10A is connected with first sputtering target 9A, and a gas barrier layer is formed on the obverse of continuous web W by sputtering film-forming by applying sputtering power from direct current sputtering electric source 10A to first sputtering target 9A. At the facing position to first film-forming roll 5A (the upper portion in the FIGURE) is arranged second sputtering target 11A for forming an under layer by sputtering on the obverse of continuous web W going along first film-forming roll 5A. Direct current sputtering electric source 12A is connected with second sputtering target 11A, and an under layer is further formed on the gas barrier layer formed on the obverse of continuous web W by sputtering film-forming by applying sputtering power from direct current sputtering electric source 12A to second sputtering target 11A. At the facing position to first film-forming roll 5A on the winding side (the left side of the upper portion in the FIGURE) is arranged third sputtering target 13A for forming a magnetic layer by sputtering on the obverse of continuous web W going along first film-forming roll 5A. Direct current sputtering electric source 14A is connected with third sputtering target 13A, and a magnetic layer is further formed on the under layer formed on the obverse of continuous web W by sputtering film-forming by applying sputtering power from direct current sputtering electric source 14A to third sputtering target 13A. At the facing position to second film-forming roll 5B on the delivery side (the right side of the lower portion in the FIGURE) is arranged first sputtering target 9B for forming a gas barrier layer by sputtering on the reverse of continuous web W going along second film-forming roll 5B. Direct current sputtering electric source 10B is connected with first sputtering target 9B, and a gas barrier layer is formed on the reverse of continuous web W by sputtering film-forming by applying sputtering power from direct current sputtering electric source 10B to first sputtering target 9B. At the facing position to second film-forming roll 5B (the lower portion in the FIGURE) is arranged second sputtering target 11B for forming an under layer by sputtering on the reverse of continuous web W going along second film-forming roll 5B. Direct current sputtering electric source 12B is connected with second sputtering target 11B, and an under layer is further formed on the gas barrier layer formed on the reverse of continuous web W by sputtering film-forming by applying sputtering power from direct current sputtering electric source 12B to second sputtering target 11B. At the facing position to second film-forming roll 5B on the winding side (the left side of the lower portion in the FIGURE) is arranged third sputtering target 13B for forming a magnetic layer by sputtering on the reverse of continuous web W going along second film-forming roll 5B. Direct current sputtering electric source 14B is connected with third sputtering target 13B, and a magnetic layer is further formed on the under layer formed on the reverse of continuous web W by sputtering film-forming by applying sputtering power from direct current sputtering electric source 14B to third sputtering target 13B. Further, sputtering gas (e.g., Ar gas) is introduced into the film forming chambers through a mass flow controller not shown in the FIGURE and sputtering pressure is optionally set.

Thus, it is preferred in the invention to form each layer, e.g., a magnetic layer, by a plurality of sputtering targets while carrying a support, and it is further preferred to use an apparatus having such a structure that a plurality of sputtering targets are arranged at counter positions to a film-forming roll.

However, the invention is not limited to the above structures, and the film-forming process may comprise a process of forming a film on one side of a support in a film-forming chamber having one film-forming roll, and then reversing the support and forming a film on the other side.

It is necessary in the invention to specify the range of the surface property of a film-forming roll. That is, a film-forming roll has a maximum surface roughness (Rz) of from 0.01 to 0.4 μm, preferably from 0.01 to 0.2 μm, and more preferably from 0.01 to 0.1 μm. A maximum surface roughness (Rz) in the invention means the value obtained in accordance with JIS B 0601-2001. By setting a maximum surface roughness (Rz) in the above range, the surface roughness of the film forming roll does not adversely influence the support and the adhesion to the support is improved, so that a lag in carrying of support can be prevented and the occurrence of defects on a medium can also be prevented. Forming of film by sputtering using such a film-forming roll can effectively release heat applied to a support and very effectual for the prevention of support deformation. A maximum surface roughness (Rz) can be adjusted by surface finishing of a film-forming roll. For example, finishing by specular polishing after hard chrome plating on the surface of a metal roll is exemplified.

For preventing a lag in carrying a support closely brought into contact with a film-forming roll, or for the support to almost face to sputtering targets, the film-forming roll is preferably large to some extent, e.g., the diameter of the roll is preferably at least 250 mm or more, more preferably 400 mm or more.

The carrying rate of a support is preferably in the range of from 0.1 to 10 m/min, more preferably from 0.1 to 8 m/min. When the carrying rate is less than 0.1 m/min, the productivity is not good, while when it exceeds 10 m/min, a high input of electric power is required and there are possibilities of the occurrence of deformation of support due to heat and cracks on a sputtered film.

It is further preferred to perform a heating degassing process of heating a support with a heater or heating drum to release the gas contained in the support before each layer, e.g., a magnetic layer, is formed on the support. As shown in FIG. 1, it is preferred that heater or heating drum 21 is provided between unwinding roller 2 and first film-forming roll 5A, but first film-forming roll 5A may be substituted for heating drum 21.

Various drums or rolls in FIG. 1 may be subjected to arbitrary surface treatments for the purpose of carrying a support without causing crinkles or flaws. For example, finishing by specular polishing after hard chrome plating on the surface of a metal roll is preferred to reduce surface roughness (Rz) to preferably 0.8 μm or less, more preferably 0.4 μm or less. By performing finishing of a roll of the surface roughness to 0.8 μm or less, the surface roughness of the roll does not transfer to a support even in carrying a smooth support closely brought into contact with the film-forming roll, and it becomes possible to manufacture a magnetic recording medium having a smooth surface.

It is preferred to provide an under layer for the purpose of the control of crystal orientation property of a magnetic layer. The under layer can also be formed with the apparatus shown in FIG. 1 according to a sputtering method. As sputtering methods, well-known DC sputtering methods and RF sputtering methods can be used.

In forming the under layer, the temperature of a support an be freely controlled in the range of from 0 to 200° C. In eating, heating of a support can be controlled by heating with heater, heating with a heating drum, or by heating a film forming roll. It is preferred to form an under layer in the state of bringing a support into contact with a film-forming roll for avoiding the deformation of the support by heat. When an under layer is formed at room temperature or a low temperature condition, the temperature of a support can be controlled by means of, e.g., cooling a film-forming roll.

General argon gases can be used as the gas in sputtering but other rare gases can also be used. A trace amount of oxygen gas may be introduced for the adjustment of crystallizability or for the purpose of surface oxidation.

In manufacturing an under layer by a sputtering method, the deposition rate is preferably from 0.5 to 20 nm/sec, particularly preferably from 0.5 to 15 nm/sec. When the deposition rate is in this range, not only the support deformation due to heat applied in film-forming time can be inhibited but also the occurrence of cracks on the sputtered film can be prevented. Further, crystallizability and film adhesion can be ensured, as well as productivity can be achieved.

A seed layer may be provided just under an under layer for the purpose of increasing crystal orientation property of the under layer and imparting electrical conductivity, and a gas barrier layer may be provided between the support and the under layer for the purpose of the improvement of adhesion and barriering of gas.

A seed layer and an under layer can be formed by vacuum film forming methods, e.g., vacuum evaporation and sputtering. Of these methods, a sputtering method is preferably used for capable of forming a high quality and hyper thin film with ease. As sputtering methods, any of well-known DC sputtering methods, RF sputtering methods and DC pulse sputtering methods can be used. As such a seed layer, Ti, W and V alloys are preferably used, but other alloys may also be used. The thickness of a seed layer is preferably from 1 to 30 nm. When the thickness of a seed layer is greater than this range, productivity decreases and at the same time noise increases due to thickening of crystal particles, while when the thickness is smaller than the above range, the effect of providing a seed layer cannot be obtained. As a gas barrier layer, a single substance of nonmetallic elements, mixtures of nonmetallic elements, or compounds comprising Ti and nonmetallic elements can be used. These materials have also resistance to the stress applied in the time of head-medium contact. The thickness of a gas barrier layer is preferably from 5 to 100 nm, particularly preferably from 5 to 50 nm. When the thickness of a gas barrier layer is greater than the above range, productivity decreases and at the same time noise increases due to thickening of crystal particles, while when the thickness is smaller than the above range, the effect of providing a gas barrier layer cannot be obtained.

A protective layer is provided for the purpose of preventing the corrosion of the metallic materials contained in a magnetic layer, and preventing the abrasion of a magnetic layer by the pseudo contact or contact sliding of a magnetic head and a magnetic disk, to thereby improve running durability and anticorrosion. Oxides such as silica, alumina, titania, zirconia, cobalt oxide, nickel oxide, etc., nitrides such as titanium nitride, silicon nitride, boron nitride, etc., carbides such as silicon carbide, chromium carbide, boron carbide, etc., and carbons such as graphite, amorphous carbon, etc., can be used in a protective layer.

A protective layer is a hard film having hardness equal to or higher than the hardness of the material of a magnetic head, and materials that hardly cause burning during sliding and stably maintain the effect are preferred, since such hard films are excellent in tribological durability. At the same time, materials having fewer pinholes are excellent in anticorrosion and preferred. As such a protective layer, hard carbon films called DLC (diamond-like carbon) are exemplified.

A protective layer may be formed by the lamination of two or more kinds of thin films having different properties. For example, it is possible to reconcile anticorrosion and durability on a high level by providing a hard carbon protective film on the surface side for improving a tribological property and a nitride protective film, e.g., a silicon nitride, on the magnetic recording layer side for improving anticorrosion.

As the apparatus for forming a protective layer, the same apparatus as the apparatus for forming a magnetic layer described above or other vacuum apparatus may be used. When a protective layer is formed with the same apparatus as shown in FIG. 1, it is preferred that the surface property of a film-forming roll Rz is as smooth as 0.4 μm or less. When the surface of a film-forming roll is very smooth, the support is not adversely influenced by the surface roughness of the roll. In addition, the adhesion to the support is also improved, so that a lag in carrying of support can be prevented and the occurrence of defects on a medium can also be prevented. As the finishing of the surface of a film-forming roll, it is preferred to finish the surface roughness (Rz) to preferably 0.4 μm or less, more preferably 0.1 μm or less, by specular polishing after hard chrome plating on the surface of a metal roll.

It is preferred for the apparatus for forming a protective layer to have a structure of forming a protective layer by means of a protective layer-forming gun while carrying a support. The protective layer-forming gun may be one or a plurality per one film-forming roll.

For preventing a lag in carrying a support closely brought into contact with a film-forming roll, or for the support to almost face to the gun, the film-forming roll used in the apparatus for forming a protective layer is preferably large to some extent, e.g., the diameter of the roll is preferably at least 250 mm or more, more preferably 400 mm or more.

In forming a protective layer, the carrying rate of a support is preferably in the range of from 0.1 to 10 m/min, more preferably from 0.1 to 8 m/min. When the carrying rate is less than 0.1 m/min, the productivity is not good, while when it exceeds 10 m/min, a high input of electric power is required and there are possibilities of the occurrence of deformation of support due to heat and cracks on the protective film.

It is preferred to perform treatment for increasing adhesion, e.g., argon treatment, before a protective layer is formed on a support.

Various carrying rolls in the apparatus for forming a protective layer may be subjected to arbitrary surface treatments for the purpose of carrying a support without causing crinkles or flaws. For example, finishing by specular polishing after hard chrome plating on the surface of a metal roll is preferred to reduce surface roughness (Rz) to preferably 0.8 μm or less, more preferably 0.4 μm or less. By the finishing of a roll of the surface roughness to 0.8 μm or less, the surface roughness of the roll does not transfer to a support even in carrying a smooth support closely brought into contact with the film-forming roll, and it becomes possible to manufacture a magnetic recording medium having a smooth surface.

A support comprises a resin film having flexibility (a flexible polymer support) for avoiding the impact in the time when a magnetic head and a magnetic disk or a magnetic tape are brought into contact. As such resin films, resin films selected from polyethylene terephthalate (PET), polyethylene naphthalate (PEN), polyamide (PA) and polyimide (PI) are preferably used, and polyethylene terephthalate (PET) and polyethylene naphthalate (PEN) are more preferred.

A laminate comprising a plurality of resin films may be used as a support. By using a laminated film, warpage and undulation resulting from a support itself can be reduced, which conspicuously improve the flaw resistance of a magnetic recording layer.

As laminating methods, roll lamination by heat rollers, lamination by plate hot press, dry lamination of laminating by coating an adhesive on the surface to be adhered, and lamination of using an adhesive sheet formed in advance in the form of a sheet are exemplified. The kinds of adhesives are not especially restricted and a general hot melt adhesive, a thermosetting adhesive, a UV-curable type adhesive, an EB-curable type adhesive, an adhesive sheet, and an anaerobic adhesive can be used.

In the case of a flexible disk, the thickness of a support is from 10 to 200 μm, preferably from 20 to 150 μm, and more preferably from 30 to 100 μm. When the thickness of a support is less than 10 μm, the stability in the time of high speed rotation decreases and run out increases. On the other hand, when the thickness is more than 200 μm, the rigidity during rotation becomes high and it is difficult to avoid the impact in the time when the magnetic disk are brought into contact with a magnetic head, which causes jumping of the magnetic head. In the case of a magnetic tape, the thickness of a support is from 1 to 20 μm, preferably from 3 to 12 μm. When the thickness of a support is less than 3 μm, the strength is insufficient, so that cutting or folding of edges are liable to occur. While when the thickness is more than 20 μm, the length of a magnetic tape that can be wound per one roll of tape becomes short, so that the volume recording density lowers. Further, since the rigidity during rotation becomes high, the touch to a magnetic head, i.e., following-up, deteriorates.

In the case of a flexible disk, the nerve of a support represented by the following equation is preferably the value of from 0.5 to 2.0 kgf/mm² (from 4.9 to 19.6 MPa) when b is 10 mm, and more preferably from 0.7 to 1.5 kgf/mm² (from 6.86 to 14.7 MPa).
Nerve of support=Ebd³/12
In the equation, E represents a Young's modulus, b represents a film breadth, and d represents a film thickness.

The surface of a support is preferably as smooth as possible for performing recording with a magnetic head. The unevenness of the surface of a support conspicuously degrades the recording and reproducing characteristics of signals. Specifically, when an undercoat layer described later is used, the surface roughness in central line average surface roughness (Ra) measured with an optical surface roughness meter is not greater than 5 nm, preferably not greater than 2 nm, and the height of spine measured with a feeler type roughness meter is not greater than 1 μm, preferably not greater than 0.1 μm. When an undercoat layer is not used, the surface roughness in central line average surface roughness (Ra) measured with an optical surface roughness meter is not greater than 3 nm, preferably not greater than 1 nm, and the height of spine measured with a feeler type roughness meter is not greater than 0.1 μm, preferably not greater than 0.06 μm.

It is preferred to provide an undercoat layer on the surface of a support for the purpose of improving a plane property and a gas barrier property. For forming a magnetic layer by sputtering, it is preferred that an undercoat layer be excellent in heat resistance. As the materials of an undercoat layer, e.g., polyimide resins, polyamideimide resins, silicone resins and fluorine resins can be used. Thermosetting polyimide resins and thermosetting silicone resins have a high smoothing effect and particularly preferred. The thickness of an undercoat layer is preferably from 0.1 to 3.0 μm. When other resin films are laminated on a support, an undercoat layer may be formed before lamination processing, or an undercoat layer may be formed after lamination processing.

As thermosetting polyimide resins, polyimide resins obtained by thermal polymerization of an imide monomer having two or more unsaturated terminal groups in the molecule, e.g., bisallylnadiimide “BANI” (manufactured by Maruzen Petrochemical Co., Ltd.), are preferably used. This imide monomer can be thermally polymerized at a relatively low temperature after being coated in the state of a monomer on the surface of a support, and so the material monomer can be directly coated on a support and cured. Further, the imide monomer can be used by being dissolved in ordinary solvents, is excellent in productivity and working efficiency, has a small molecular weight, and a solution of the imide monomer is low in viscosity, so that it gets into the unevenness well in coating and is excellent in smoothing effect.

As thermosetting silicone resins, silicone resins obtained by polymerization by a sol-gel method with silicone compounds having introduced an organic group as the starting material are preferably used. The silicone resins have a structure in which a part of the silicon dioxide bonds is substituted with an organic group, and the resins are greatly excellent in heat resistance as compared with silicone rubbers and more flexible than silicon dioxide films, so that cracking and peeling are hardly generated when a film of the silicone resins is formed on a support comprising a flexible film. In addition, since the starting material monomers can be directly coated on a support and hardened, general-purpose solvents can be used, the resins get into the unevenness well, and smoothing effect is high. Further, since condensation polymerization reaction advances from comparatively low temperature by the addition of a catalyst such as an acid and a chelating agent, hardening can be expedited, and a resin film can be formed with a general-purpose coating apparatus. Thermosetting silicone resins are excellent in a gas barrier property of shielding gases generating from a support when a magnetic layer is formed and hindering the crystallizability and orientation of the magnetic layer and the under layer, so that they can be particularly preferably used.

It is preferred to provide minute spines (texture) on the surface of an undercoat layer for the purpose of reducing the real contact area of a magnetic head and a magnetic disk and improving a tribological property. Further, the handling property of a support can be improved by providing minute spines. As a method of forming minute spines, a method of coating spherical silica particles and a method of coating an emulsion to thereby form the spines of an organic substance can be used, and the method of forming minute spines by coating spherical silica particles is preferred for ensuring the heat resistance of the undercoat layer.

The height of minute spines is preferably from 5 to 60 nm, more preferably from 10 to 30 nm. When the height of minute spines is too high, the recording/reproducing characteristics of signals are deteriorated by the spacing loss between the recording/reproducing heads and the medium. While when the height of minute spines is too low, the improving effect of a tribological property can be hardly achieved. The density of minute spines is preferably from 0.1 to 100/μm², and more preferably from 1 to 10/μm². When the density of minute spines is two low, the improving effect of a tribological property can be hardly obtained, and when the density is too high, agglomerated particles increase, and high spines increase, so that recording/reproducing characteristics deteriorate.

Minute spines can also be fixed on the surface of a support with a binder. It is preferred to use resins having sufficient heat resistance as the binder. As the resins having heat resistance, solvent-soluble polyimide resins, thermosetting polyimide resins and thermosetting silicone resins are particularly preferably used.

A lubricating layer is provided on a protective layer for improving running durability and anticorrosion. Lubricants, e.g., well-known hydrocarbon lubricants, fluorine lubricants and extreme pressure additives, are used in a lubricating layer.

As hydrocarbon lubricants, carboxylic acids, e.g., stearic acid and oleic acid, esters, e.g., butyl stearate, sulfonic acids, e.g., octadecylsulfonic acid, phosphoric esters, e.g., monooctadecyl phosphate, alcohols, e.g., stearyl alcohol and oleyl alcohol, carboxylic acid amides, e.g., stearic acid amide, and amines, e.g., stearylamine, are exemplified.

The examples of fluorine lubricants include lubricants obtained by substituting a part or all of the alkyl groups of the above hydrocarbon lubricants with fluoroalkyl groups or perfluoropolyether groups. The examples of perfluoropolyether groups include a perfluoromethylene oxide polymer, a perfluoroethylene oxide polymer, a perfluoro-n-propylene oxide polymer [(CF₂CF₂CF₂O)ₙ], a perfluoroisopropylene oxide polymer {[CF(CF₃)CF₂O)]ₙ}, and copolymers of these polymers. Specifically, perfluoromethylene-perfluoroethylene copolymers having hydroxyl groups at molecular chain terminals (FOMBLIN Z-DOL, trade name, manufactured by AUSIMONT K.K.) are exemplified.

As extreme pressure additives, phosphoric esters, e.g., trilauryl phosphate, phosphorous esters, e.g., trilauryl phosphite, thiophosphorous esters, e.g., trilauryl trithiophosphite, and sulfur extreme pressure additives, such as thiophosphoric esters and dibenzyl disulfide are exemplified.

These lubricants can be used alone or a plurality of lubricants can be used in combination. A lubricating layer can be formed by coating a solution obtained by dissolving a lubricant in an organic solvent on the surface of a protective layer by spin coating, wire bar coating, gravure coating or dip coating, alternatively by depositing a lubricant on the surface of a protective layer by vacuum evaporation. The coating amount of a lubricant is preferably from 1 to 30 mg/m², and particularly preferably from 2 to 20 mg/m².

It is preferred to use rust preventives in combination with a lubricant for bettering anticorrosion. As the examples of rust preventives, nitrogen-containing heterocyclic rings, e.g., benzotriazole, benzimidazole, purine and pyrimidine, derivatives obtained by introducing alkyl side chains to the mother nuclei of these nitrogen-containing heterocyclic rings, nitrogen- and sulfur-containing heterocyclic rings, e.g., benzothiazole, 2-mercaptobenzothiazole, tetraazaindene ring compounds and thiouracil compounds, and derivatives of these heterocyclic rings are exemplified. A rust preventive may be mixed with a lubricant and coated on a protective layer, alternatively a rust preventive may be coated on a protective layer prior to the coating of a lubricant, and then a lubricant may be coated thereon. The coating amount of rust preventives is preferably from 0.1 to 10 mg/m², and particularly preferably from 0.5 to 5 mg/m².

In the case of a magnetic tape, it is preferred to provide a back coat layer on the side of a flexible polymer support opposite to the side on which a magnetic layer is provided. A back coat layer has a lubricating effect to prevent abrasion of the back surface of a magnetic recording medium when the magnetic recording medium is slid with a sliding member. By adding a lubricant and a rust preventive as used in a lubricating layer, the lubricant and rust preventive are supplied from the back coat layer side to the magnetic layer side, so that the anticorrosion of the magnetic layer can be maintained for a long period of time. The anticorrosion of the magnetic layer can also be further increased by the adjustment of the pH of the back coat layer itself. A back coat layer can be formed by coating a solution obtained by dispersing nonmagnetic powders, e.g., carbon black, calcium carbonate, alumina, etc., resinous binders, e.g., polyvinyl chloride, polyurethane, etc., a lubricant and a hardening agent in an organic solvent by gravure coating or wire bar coating, and then drying. A rust preventive and a lubricant may be dissolved in the above back coat layer coating solution, or they may be coated on a back coat layer manufactured.

### EXAMPLES

The invention will be described more specifically with referring to examples and comparative examples, but the invention is not limited thereto.

### Example 1

An undercoat layer coating solution comprising 3-glycidoxypropyltrimethoxysilane, phenyltriethoxysilane, hydrochloric acid, aluminum acetylacetonate and ethanol was coated on a polyethylene naphthalate film as a support having a thickness of 53 μm and surface roughness (Ra) of 1.4 nm by gravure coating, and the coated solution was subjected to drying and curing at 100° C., thereby an undercoat layer having a thickness of 1.0 μm comprising a silicone resin was formed. A mixed coating solution comprising silica sol having a particle size of 25 nm and the above undercoat layer coating solution was coated on the undercoat layer by gravure coating, thereby spines having a height of 15 nm were formed on the undercoat layer in density of 10/μm². The undercoat layer was formed on both sides of the support. The web was mounted on the web-carrying sputtering apparatus shown in FIG. 1, and the following layers were formed on the undercoat layer by a DC magnetron sputtering method by carrying the web with being closely brought into contact with a can having a maximum surface roughness (Rz) of 0.05 μm cooled with water at a carrying rate of 1 m/min: a gas barrier layer comprising C having a thickness of 30 nm; an under layer comprising Ru having a thickness of 20 nm on the conditions of Ar pressure of 2 Pa, and the input of electric power of 5 W/cm²; and a magnetic layer comprising (Co₇₀—Pt₂₀—Cr₁₀)₈₈—(SiO₂)₁₂ having a thickness of 20 nm on the conditions of a deposition rate of 2 nm/sec, an opening breadth in the moving direction of the film of 166 mm, Ar pressure of 2 Pa, and the input of electric power of 5 W/cm². The maximum surface roughness (Rz) of first film forming roll 5A and second film forming roll 5B was 0.05 μm. The distance between the sputtering target of a magnetic layer and a support was 75 mm. These gas barrier layer, under layer and magnetic layer were formed on both sides of the film. Subsequently, the web was mounted on a web type protective layer forming apparatus, and a nitrogen added DLC protective layer comprising C/H/N of 62/29/7 in molar ratio and 5 nm in thickness was formed by an ion beam process using ethylene gas, nitrogen gas and argon gas as reaction gases. The protective layer was also provided on both sides of the film. In the next place, a lubricating layer having a thickness of 1 nm was formed on the surface of the protective layer by coating a solution obtained by dissolving a perfluoropolyether lubricant having hydroxyl groups at the molecule terminals (FOMBLIN Z-DOL, manufactured by Montefluos Ltd.) in a fluorine lubricant (HFE-7200, manufactured by Sumitomo 3M Limited) by gravure coating. The lubricating layer was also formed on both sides of the film. A 3.7 inch size magnetic disk was punched out of the web, subjected to tape burnishing treatment, and built into a resin cartridge (for Zip 100, manufactured by Fuji Photo Film Co., Ltd.), whereby a flexible disk was obtained.

### Example 2

A flexible disk was manufactured in the same manner as in Example 1 except that a magnetic layer having a thickness of 20 nm was formed on the conditions of a deposition rate of 15 nm/sec and Ar pressure of 3 Pa.

### Example 3

A flexible disk was manufactured in the same manner as in Example 1 except for using a polyethylene terephthalate film having a thickness of 63 μm and surface roughness (Ra) of 1.0 nm as the support.

### Example 4

A flexible disk was manufactured in the same manner as in Example 1 except for forming a magnetic layer with a DC pulse sputtering method. The conditions of the DC pulse sputtering method were reverse time of 0.5 μs and pulse frequency of 100 kHz.

### Example 5

A gas barrier layer, an under layer, a magnetic layer and a protective layer were formed on one side of a polyamide film having a thickness of 9 μm and a surface roughness (Ra) of 1.0 nm as a support in the same manner as in Example 1. After the protective layer was formed, a back coat layer comprising carbon black was formed on the other side of the support, whereby a magnetic tape having a width of 8 mm was manufactured.

### Comparative Example 1

A flexible disk was manufactured in the same manner as in Example 1 except that a magnetic layer was formed at a deposition rate of 25 nm/sec.

### Comparative Example 2

A flexible disk was manufactured in the same manner as in Example 1 except that a first film-forming roll and a second film-forming roll having a maximum surface roughness (Rz) of 1.0 μm were used.

Evaluation:

Each magnetic recording medium obtained above was evaluated as follows.

(1) Magnetic Characteristics

Coercive force (Hc) was measured by VSM.

(2) Run Out

Each of the above flexible disks was rotated at 3,000 rpm and the run out of each disk at the radius position of 35 mm was measured with a laser displacement gauge.

(3) Occurrence of Cracks

The surface of each magnetic medium was observed with an optical microscope and the occurrence of a crack was evaluated.

The results obtained are shown in Table 1 below.

TABLE 1

| | Hc | Run Out | Occurrence |
|---|---|---|---|
| Example No. | (kA/m) | (μm) | of Crack |
| Example 1 | 250 | 25 | No |
| Example 2 | 265 | 30 | No |
| Example 3 | 255 | 20 | No |
| Example 4 | 260 | 25 | No |
| Example 5 | 250 | — | No |
| Comparative | 250 | 55 | Yes |
| Example 1 | | | |
| Comparative | 245 | 40 | No |
| Example 2 | | | |

It is apparent from the results in Table 1 that the flexible disks manufactured according to the manufacturing method in the invention are not only little in run out but also they are free from the occurrence of a crack on the sputtered films and high in productivity of samples. On the other hand, although the samples in Comparative Examples 1 and 2 that were manufactured with a high deposition rate or by using a rough film-forming roll showed the magnetic characteristics similar to those of the samples in the invention, run out increased and cracks occurred, so that these disks cannot be said as media having high reliability.

This application is based on Japanese Patent application JP 2004-173765, filed Jun. 11, 2004, the entire content of which is hereby incorporated by reference, the same as if set forth at length.

1. A method for manufacturing a magnetic recording medium comprising a flexible polymer support and a magnetic layer, the method comprising forming the magnetic layer on at least one side of the flexible polymer support by a sputtering method, wherein the flexible polymer support contains at least one of polyethylene terephthalate, polyethylene naphthalate, polyamide and polyimide, the forming of the magnetic layer is carried out while carrying the flexible polymer support along a roll having a maximum surface roughness of from 0.01 to 0.4 μm, and a deposition rate in the forming of a magnetic layer is from 0.5 to 17 nm/sec.

2. The method according to claim 1, wherein the flexible polymer support is carried in the forming of a magnetic layer at a rate of 0.1 to 10 m/minute.

3. The method according to claim 1, wherein the flexible polymer support is carried in the forming of a magnetic layer at a rate of 0.1 to 8 m/minute.

4. The method according to claim 1, wherein the roll has a maximum surface roughness of from 0.01 to 0.2 μm.

5. The method according to claim 2, wherein the roll has a maximum surface roughness of from 0.01 to 0.2 μm.

6. The method according to claim 1, wherein the roll has a maximum surface roughness of from 0.01 to 0.1 μm.

7. The method according to claim 2, wherein the roll has a maximum surface roughness of from 0.01 to 0.1 μm.

8. The method according to claim 1, wherein the roll has a diameter of 250 mm or more.

9. The method according to claim 1, wherein the roll has a diameter of 400 mm or more.

10. The method according to claim 1, wherein a deposition rate in the forming of a magnetic layer is from 0.5 to 10 nm/sec.

11. The method according to claim 2, wherein a deposition rate in the forming of a magnetic layer is from 0.5 to 10 nm/sec.

12. The method according to claim 1, wherein the flexible polymer support contains polyethylene terephthalate or polyethylene naphthalate.

13. The method according to claim 2, wherein the flexible polymer support contains polyethylene terephthalate or polyethylene naphthalate.

14. The method according to claim 1, wherein the magnetic recording medium is a flexible disk, and the support has a thickness of from 10 to 200 μm.

15. The method according to claim 1, wherein the magnetic recording medium is a flexible disk, and the support has a thickness of from 20 to 150 μm.

16. The method according to claim 1, wherein the magnetic recording medium is a flexible disk, and the support has a thickness of from 30 to 100 μm.

17. The method according to claim 1, wherein the magnetic recording medium is a magnetic tape, and the support has a thickness of from 1 to 20 μm.

18. The method according to claim 1, wherein the magnetic recording medium is a magnetic tape, and the support has a thickness of from 3 to 12 μm.
